(19) United States
(12) Patent Application Publication
(10) Pub. No.: US 2006/0246358 A1
(43) Pub. Date: Nov. 2, 2006

(54) DEVICE AND METHOD TO TREAT BLOOD VESSELS IN THE EYE

(76) Inventor: Edwin Ryan, St. Paul, MN (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/276,882

(22) Filed: Mar. 17, 2006

Related U.S. Application Data
(60) Provisional application No. 60/662,836, filed on Mar. 17, 2005.

(51) Int. Cl. G03F 1/00

(52) U.S. Cl. 430/5

(57) ABSTRACT

A device and method to treat blood vessels in the eye is shown. Advantages of devices and methods shown include reduced beam exposure of healthy tissue during a treatment procedure. Another advantage includes the ability to modify beam exposure to individual patient needs. Another advantage includes the ability to utilize imaging software to create a complex beam geometry.

### RELATED APPLICATIONS

This application claims the benefit of U.S. Provisional Application Ser. No. 60/662,836, filed Mar. 17, 2005, which provisional application is incorporated herein by reference.

### TECHNICAL FIELD

This invention relates to devices and methods to treat blood vessels in the eye. Specifically, this invention relates to treating blood vessels with an energy beam such as laser light.

### BACKGROUND

Photodynamic therapy has become widely used for treatments of the eye. One common example uses Visudyne products for treatment of exudative macular degeneration. Current treatment involves drug infusion followed by low-powered laser irradiation of the area affected with a circular pattern of a specific wavelength laser large enough to cover all of the area suspected to have active blood vessel leakage. However, the pattern of active blood vessel leakage can be widely varied to any of a number of geometries such as a long linear pattern, etc. The pattern of laser irradiation based on current equipment is a circle that has a diameter 1 mm beyond the greatest linear dimension of the blood vessel lesion area to be treated. Using a circular beam area is not selective to the particular blood vessel lesions to be treated, and a large area of healthy or uninvolved retina can be put at risk for laser related complications such as ischemia. In addition, when using a general exposure area such as a circular beam, peripapillary lesions cannot be irradiated adequately without exposing the optic nerve to risk of ischemia.

What is needed is an improved device and method for laser treatment of the eye. What is also needed is a treatment method and device that reduces risk to surrounding healthy tissue.

### BRIEF DESCRIPTION OF THE DRAWINGS

FIG. 1 shows an example of an eye treatment device according to an embodiment of the invention.

FIG. 2A shows an example of a mask pattern according to an embodiment of the invention.

FIG. 2B shows another example of a mask pattern according to an embodiment of the invention.

FIG. 3 shows an isometric view of multiple mask patterns according to an embodiment of the invention.

FIG. 4 shows another example of a mask pattern according to an embodiment of the invention.

FIG. 5 shows a method flow diagram according to an embodiment of the invention.

### DETAILED DESCRIPTION

In the following detailed description, reference is made to the accompanying drawings which form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, optical, electrical, mechanical or logical changes, etc. may be made without departing from the scope of the present invention. In the present disclosure, a laser is used as an example. Although laser light is specifically discussed, it will be appreciated that the invention includes any effective wavelength of beam energy, and other effective forms of light aside from laser light such as non-coherent beam sources.

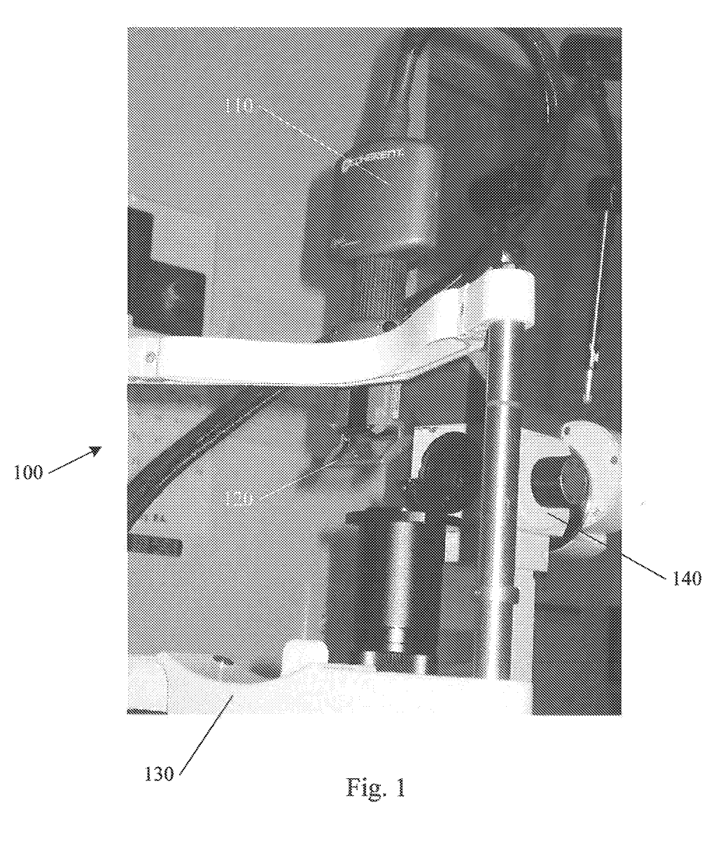

FIG. 1 shows an eye treatment device 100. The eye treatment device 100 includes an energy beam source 110, and a patient stabilizing portion 130. In one embodiment, the patient stabilizing portion includes a chin rest or similar device to hold the patient steady while features in the eye are viewed, or treatment is performed. In one embodiment, a turning mirror 120 is included. In one embodiment, the mirror 120 is partially reflective, allowing a practitioner to use a viewing device 140 to view along a path that a generated energy beam will travel. Although a turning mirror 120 is shown in FIG. 1, alternate embodiments do not include a turning mirror.

In one embodiment, the energy beam source 110 includes a light source of approximately 698 nm wavelength. In one embodiment, the wavelength is chosen to react with a corresponding optically reactive drug. In one embodiment the energy beam includes laser light, such as 698 nm wavelength laser light. In one embodiment, features such as a beam homogenizer are further included to provide an even distribution of energy across an areal geometry of the beam. In one embodiment the energy beam source 110 provides a circular areal geometry. In one embodiment, a radius of the circular areal geometry is adjustable using an aperture or other adjustment device.

While a circular areal cross section is useful in many procedures, as stated above, such a beam is not selective to the particular blood vessel lesions to be treated, and a large area of healthy or uninvolved retina can be put at risk for laser related complications. In one embodiment of the invention a beam modification device is provided to change the areal geometry from circular in the present example to a second areal geometry that more directly targets the area to be treated, and reduces exposure to healthy tissue. In one embodiment, the beam modification device can be varied to substantially match the needed treatment area of each individual procedure.

A number of possible beam modification devices are contemplated within the scope of the invention. Beam modification devices include, but are not limited to, single mask configurations, multiple mask configurations, electronically generated mask configurations, electronically controlled mask configurations, etc. Other non-masking beam modification devices are also within the scope of the invention, such as lenses or other optical refraction devices. Although some example beam modification techniques are listed above, the invention is not so limited. Any device, or combination of devices that changes a beam from a first areal geometry to a second areal geometry is within the scope of the invention.

In the present description, a change in areal beam geometry is distinguished from a change in magnitude. Devices such as apertures can change a circular beam area from a large diameter to a small diameter, however, devices such as an aperture do not change an areal geometry, for example, from a circle to a rectangle. Although a circular beam geometry is used as an example for a first areal beam geometry, other beam generation devices with first areal beam geometries such as squares, ovals, etc. are also within the scope of the invention. Some examples of beam modification devices that change a beam areal geometry from a first areal geometry to a second areal geometry are shown in the following Figures.

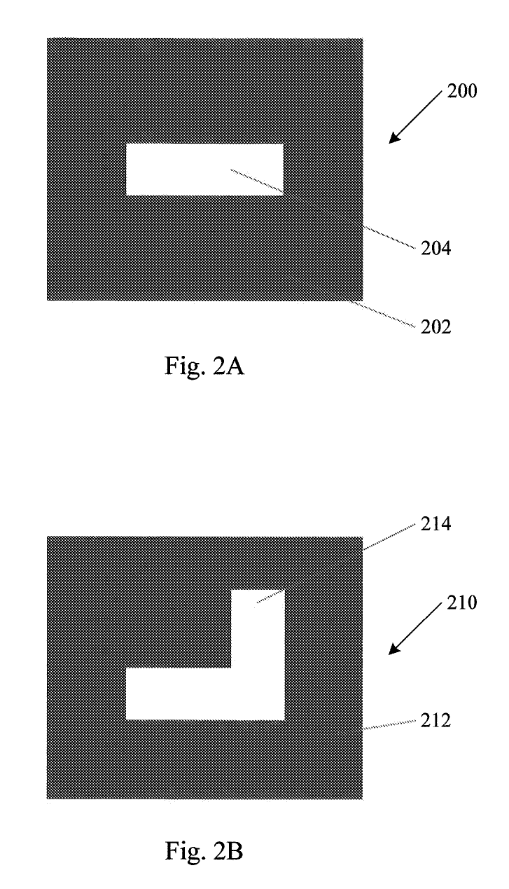

FIG. 2A shows a beam modification device according to an embodiment of the invention. Specifically, FIG. 2A shows a mask 200. The mask 200 includes a low transmission portion 202 and a high transmission portion 204. In one embodiment, the low transmission portion 202 is opaque, and the high transmission portion 204 is transparent. Other embodiments include a high transmission portion 202 that attenuates some of the beam energy. In one embodiment, the low transmission portion 202 allows some beam energy to pass through, but at a level that is lower than the high transmission portion 204.

In one embodiment, the high transmission portion 204 includes an area that is removed completely from an opaque sheet. In one embodiment, a transparent sheet is coated with an opaque material to create the low transmission portion 202. In one embodiment, the mask 200 includes an electronic mask such as an LCD generated mask. In one embodiment, an LCD device electronically generates the low transmittance portion 202 to define the high transmittance portion 404. In one embodiment, the pattern data to determine the geometry of the high transmittance portion 404 is provided by user input. In one embodiment, the geometry of the high transmittance portion 404 is provided from a patient imaging device that is discussed in more detail below. FIG. 2A shows a high transmission portion 204 with a rectangular geometry as one possible example geometry.

In one method of operation, a mask such as mask 200 is placed at a location along a beam path in a device such as eye treatment device 100 shown in FIG. 1. The low transmission portion 202 attenuates a portion of a first areal geometry, while the high transmission portion 204 allows a higher transmittance of beam energy. In this way, the mask modifies a first beam areal geometry to a second areal geometry. For example, the mask 200 from FIG. 2A modifies a circular beam geometry to a rectangular geometry.

FIG. 2B shows a second mask 210. Similar to the example mask 200 shown in FIG. 2A, the second mask 210 includes a low transmission portion 212 and a high transmission portion 214. Similar to the mask 200 of FIG. 2A, in one embodiment, the low transmission portion 202 is opaque, and the high transmission portion 204 is transparent. FIG. 2B shows a high transmission portion 214 with a more complex “L” shaped geometry as one possible example geometry. Although geometries with straight edges and corners are shown in FIGS. 2A and 2B, other geometries including curves, arcs, etc. are also within the scope of the invention.

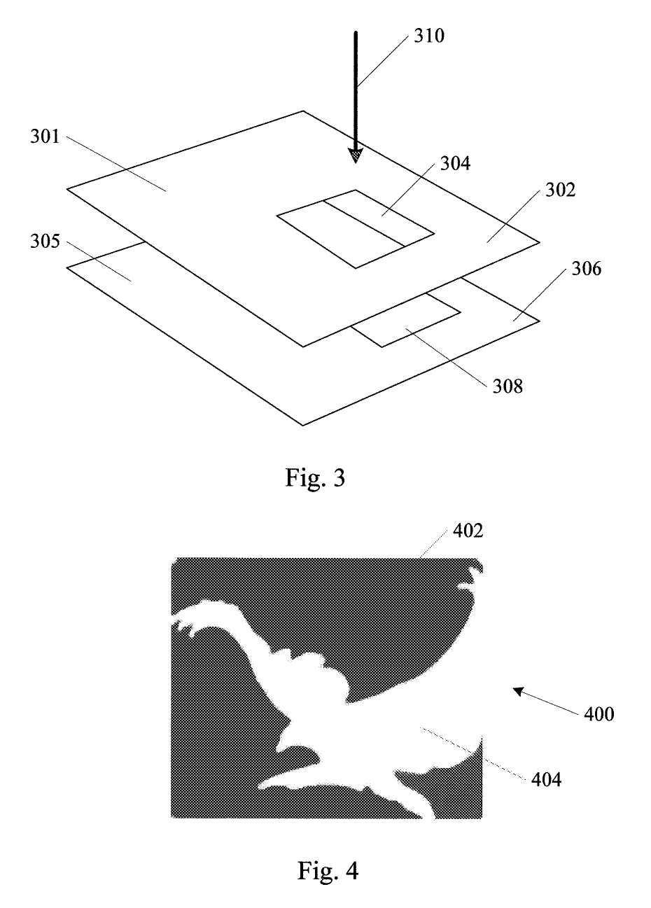

FIG. 3 shows a mask configuration according to an embodiment of the invention. A first mask 301 is shown adjacent to a second mask 305. Similar to embodiments described above, the first mask 301 includes a low transmission portion 302 and a high transmission portion 304. Likewise, the second mask 305 includes a low transmission portion 306 and a high transmission portion 308. In one embodiment, the high transmission portion 304 and the high transmission portion 308 have different geometries, such that when placed adjacent to each other, they form a composite geometry. A beam path is indicated by arrow 310. In one embodiment, the beam path is substantially normal to the masks 301, 305, although the invention is not so limited. In one embodiment, the beam path 310 is incident at approximately 45 degrees to the masks 301, 305.

In one embodiment, a plurality of masks, such as the first mask 301 and the second mask 305 illustrated in FIG. 3, are combined together to define a composite high transmission portion. In FIG. 3, the low transmission portion 302 of the first mask 301 and the low transmission portion 306 of the second mask 305 combine to define edges of a composite high transmission portion. In this way, a plurality of masks are combined in one embodiment to modify a first beam areal geometry to a complex second areal geometry. In one embodiment, a plurality of masks are stacked together in close proximity to form the composite high transmission portion, although the invention is not so limited. In one embodiment, individual masks in the plurality of masks are located at different locations along a path of the beam.

Using the eye treatment device 100 from FIG. 1 as an example, in one embodiment one or more masks are placed in the path of the beam between the energy beam source 110 and the turning mirror 120. In one embodiment, one or more masks are places on the turning mirror 120. In one embodiment, one or more masks are placed between the turning mirror 120 and a patient. The above examples of mask locations are also applicable to non-mask beam modification devices. In one embodiment, for example, a refraction beam modification device is placed at one or more of the locations described above to modify a first beam areal geometry to a second areal geometry.

FIG. 4 shows a mask 400 according to an embodiment of the invention. Similar to the example masks discussed above, the mask 400 includes a low transmission portion 402 and a high transmission portion 404. Similar to masks discussed above, in one embodiment, the low transmission portion 402 is opaque, and the high transmission portion 404 is transparent. In one embodiment, the geometry of the high transmission portion is individually customized for each patient. As shown in FIG. 4, for selected applications, a relatively complex geometry is utilized to select only the desired area of a patient's eye.

In one embodiment, in order to determine the area to be treated, an imaging system such as available from Ophthalmic Imaging Systems (OIS) or other imaging device, is used to image the patient's retina. In one embodiment an imaging system and method includes fluorescein angiography. In one embodiment, image characteristics such as contrast, color, brightness, etc. are used to automatically select the area to be treated. In one embodiment, a treatment specialist such as a surgeon manually selects a region to be treated using computer software for example. In one embodiment, the mask 400 shown in FIG. 4 is generated automatically using data from imaging software and imaging devices described above. In one embodiment the mask 400 is printed and subsequently located in the path of the beam as described in embodiments above. In one embodiment, the mask 400 is generated using an electronic mask system such as an LCD system as described above. Data from imaging software and devices can also be used to control non-mask beam modification devices in one embodiment.

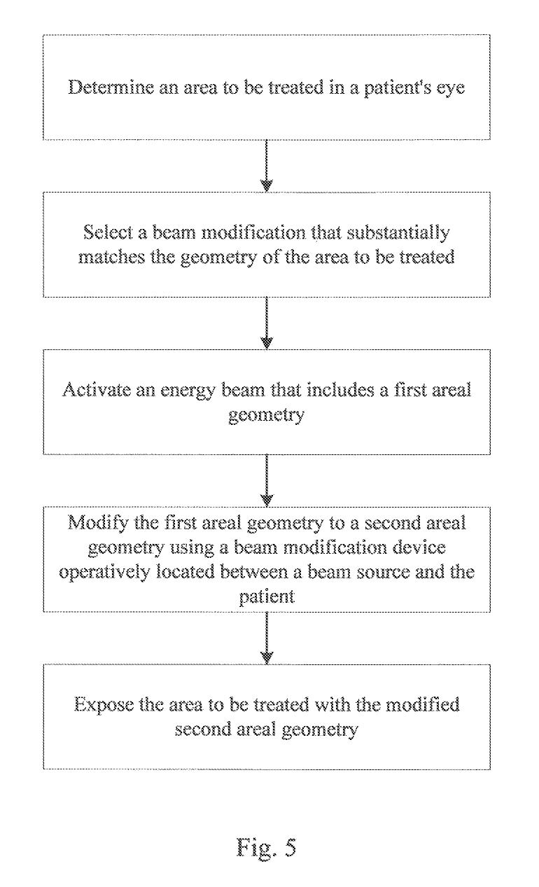

FIG. 5 shows a method according to an embodiment of the invention. As shown, an area to be treated is determined with respect to an individual patient. In one method, imaging systems as described above are used to determine the area to be treated. A beam modification is then determined to substantially match the geometry of the area to be treated.

Any of the beam modification devices described in embodiments above can be used to provide such modification. For example, in one embodiment a mask is selected from a number of pre-fabricated masks. The selected mask substantially matches the area to be treated. In one embodiment, more than one mask is selected, so that when combined, a composite mask pattern substantially matches the area to be treated. In one embodiment, an electronic mask pattern is generated using imaging data. In one embodiment, the mask pattern is printed. In one embodiment, the data is used to electronically control a mask. In one embodiment, a non-mask beam modification device is used to provide beam geometry modification.

The beam is activated with the selected choice of beam modification device in place, thus providing a second areal geometry of the beam. Because the modified second areal geometry substantially matches the area to be treated, a level of risk to the patient is reduced.

### CONCLUSION

Thus has been shown a device and method to treat blood vessels in the eye. Advantages of devices described above include reduced exposure of healthy tissue during a treatment procedure. Another advantage includes the ability to modify beam exposure to patient specific needs. Another advantage includes the ability to utilize imaging software to create a complex beam geometry.

While a number of advantages of embodiments described herein are listed above, the list is not exhaustive. Other advantages of embodiments described above will be apparent to one of ordinary skill in the art, having read the present disclosure. Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. It is to be understood that the above description is intended to be illustrative, and not restrictive. Combinations of the above embodiments, and other embodiments will be apparent to those of skill in the art upon reviewing the above description. The scope of the invention includes any other applications in which the above structures and fabrication methods are used. The scope of the invention should be determined with reference to the appended claims, along with the full scope of equivalents to which such claims are entitled.

I claim:

1. An eye treatment system, comprising:
a frame;
an energy beam source coupled to the frame to provide an energy beam with a first areal geometry;
a patient support coupled to the frame to locate a patient eye within a beam path; and
a beam modification device located along the beam path, wherein the first areal geometry is modified to a second areal geometry to match an individual patient treatment area.

2. The eye treatment system of claim 1, wherein the beam modification device includes a mask placed within the energy beam.

3. The eye treatment system of claim 1, further including an imaging system, wherein patient specific data is generated by the imaging system and used by the beam modification device to create a patient specific second areal geometry.

4. An eye treatment system, comprising:
an imaging device to provide an image of the retina of a patient's eye software to select an area of the retina for treatment from the image;
an energy beam source to provide an energy beam with a first areal geometry; and
a beam modification device, wherein the first areal geometry is modified to a second areal geometry substantially the same as a selected area of the retina from the image.

5. The eye treatment system of claim 4, wherein the beam modification device includes a mask placed within the energy beam.

6. The eye treatment system of claim 4, wherein the mask includes a solid mask.

7. The eye treatment system of claim 4, wherein a mask transmittance is electronically controllable.

8. The eye treatment system of claim 7, wherein the mask includes an LCD device.

9. The eye treatment system of claim 4, wherein the beam modification device includes a refraction device within the energy beam.

10. The eye treatment system of claim 9, wherein the refraction device includes a lens.

11. The eye treatment system of claim 4, wherein the energy beam source includes laser light.

12. The eye treatment system of claim 4, wherein the energy beam source includes 689 nm wavelength radiation.

13. An eye treatment system, comprising:
an energy beam source to provide an energy beam with a first areal geometry;
a mask holder located between the energy beam source and the patient's eye; and
a number of mask patterns to selectively block a portion of the beam within the first areal geometry; wherein a number of second areal geometric patterns are provided by the number of mask patterns.

14. The eye treatment system of claim 13, wherein the mask holder is configured to hold more than one mask pattern to form a composite mask geometry.

15. The eye treatment system of claim 13, further including an imaging system and a mask generating device, wherein patient specific data is generated by the imaging system and used by the mask generating device to create a patient specific mask pattern.

16. A method, comprising:
determining a treatment area geometry within an eye;
selecting a beam modification technique to substantially match the treatment area geometry; and
exposing the treatment area geometry within the eye to an energy beam, wherein a first beam areal geometry is modified to substantially match the treatment geometry using the beam modification technique.

17. The method of claim 16, wherein selecting a beam modification technique includes selecting a refraction technique.

18. The method of claim 16, wherein selecting a beam modification technique includes selecting a beam masking technique.

19. The method of claim 18, wherein selecting a beam masking technique includes selecting a pre-formed mask from a number of possible masks.

20. The method of claim 18, wherein selecting a beam masking technique includes selecting more than one pre-formed mask from a number of possible masks and implementing the masks in series to provide a desired beam areal geometry.

21. The method of claim 16, wherein selecting a beam modification technique includes selection based on patient specific imaging data.

22. The method of claim 21, wherein patient specific imaging data includes data from fluorescein angiography.

23. The method of claim 16, wherein exposing the treatment area geometry within the eye to the energy beam includes exposing the treatment area geometry within the eye to a laser beam.

24. A machine-readable medium with instructions stored thereon, the instructions when executed operable to cause:
imaging of a portion of an eye;
selection of a region of an eye to be treated; and
collection of beam modification data to be used by a beam modification device to modify a first beam geometry to a second beam geometry that substantially matches the selected region of the eye to be treated.
